(19) United States
(12) Patent Application Publication
(10) Pub. No.: US 2022/0040883 A1
(43) Pub. Date: Feb. 10, 2022

(54) METHOD FOR PRODUCING SEMICONDUCTOR WAFERS BY MEANS OF A WIRE SAW

(71) Applicant: SILTRONIC AG, München (DE)

(72) Inventors: Axel BEYER, Munich (DE); Carl FRINTERT, Muehldorf am Inn (DE); Peter WIESNER, Reut (DE); Wolfgang GMACH, Emmerting (DE); Robert KREUZEDER, Wurmannsquick (DE)

(73) Assignee: SILTRONIC AG, Munich (DE)

(21) Appl. No.: 17/414,717

(22) PCT Filed: Dec. 12, 2019
(86) PCT No.: PCT/EP2019/084799

§ 371 Date: Jun. 16, 2021

(30) Foreign Application Priority Data
Dec. 17, 2018 (DE) 10 2018 221 921.4

(51) Int. Cl. B28D 5/04; B28D 5/00; H01L 21/67

(52) U.S. Cl. CPC B28D 5/045; H01L 21/67092; H01L 21/67253; B28D 5/0082

(57) ABSTRACT

Semiconductor wafers with improved geometry are produced from a workpiece by processing the workpiece by means of a wire saw, by
feeding the workpiece through an arrangement of wires which are tensioned between wire guide rollers and move in a running direction;
producing kerfs when the wires engage into the workpiece;
determining a placement error of the kerfs; and
inducing a compensating movement of the workpiece as a function of the determined placement error along a longitudinal axis of the workpiece during the feeding of the workpiece through the arrangement of wires.

### CROSS REFERENCE TO RELATED APPLICATIONS

This application is the U.S. National Phase of PCT Appln. No. PCT/EP2019/084799 filed Dec. 12, 2019, which claims priority to German Application No. DE 10 2018 221 921.4, filed Dec. 17, 2018, the disclosures of which are incorporated in their entirety by reference herein.

### BACKGROUND OF THE INVENTION

### 1. Field of the Invention

The invention relates to a method for producing semiconductor wafers from a workpiece by processing the workpiece by means of a wire saw.

### 2. Description of the Related Art

JP 11 165 251 A discloses a method for producing wafers from a workpiece (ingot) by means of a wire saw, which comprises the following steps: detecting the magnitude and the direction of the deflection of wires of a wire field of the wire saw along an axial direction of the workpiece and, depending on the result of the detection, inducing a compensation movement of the workpiece in order to correct the deflection of the wires.

JP 2000 15 552 A discloses a similar method, which comprises the following steps: at the instant of a reversal of the running direction of the wires, inducing a compensation movement of the workpiece along an axial direction of the workpiece in the scope of a predetermined magnitude, the magnitude being predetermined in such a way that the deflection of the wires is corrected at the instant of the reversal of the running direction of the wires.

U.S. Pat. No. 5,875,770 discloses a similar method, which comprises the following steps: detecting a warp curve of wafers before processing the workpiece, and inducing a compensation movement of the workpiece along an axial direction of the workpiece in a scope such that wafers with reduced warp are formed.

Regardless of these available solutions, there is still a need for improvement of the method for producing semiconductor wafers from a workpiece by means of a wire saw. In particular, it is to be taken into account that the workpiece and the wires execute relative movements, for example as a result of thermal expansion of the workpiece and/or of the wire guide rollers, which has a detrimental effect on the local planarity of the semiconductor wafers.

In particular, improvement of the method is required so that semiconductor wafers are available whose planarity, particularly in relation to warp and nanotopography, is better than that of wafers which are produced in a known way.

The described set of problems gave rise to the object of the invention.

### SUMMARY OF THE INVENTION

The object of the invention is achieved by a method for producing semiconductor wafers from a workpiece by processing the workpiece by means of a wire saw, comprising

feeding the workpiece through an arrangement of wires which are tensioned between wire guide rollers and move in a running direction;

producing kerfs when the wires cut into the workpiece;

determining a placement error of the kerfs; and

inducing a compensating movement of the workpiece as a function of the determined placement error along a longitudinal axis of the workpiece during the feeding of the workpiece through the arrangement of wires.

### BRIEF DESCRIPTION OF THE DRAWINGS

FIG. 1 shows features of a wire saw which is suitable for carrying out the method according to the invention.

FIG. 2 shows how an actual trajectory through the middle of a kerf may differ from a target trajectory.

FIG. 3 shows a correction profile.

FIGS. 4 to 9 show height lines, derived from median surfaces of a warp measurement, respectively of three semiconductor wafers.

FIGS. 10 to 12 correspond to FIGS. 4 to 6 with the difference of more highly resolved scaling of the ordinate.

FIGS. 13 TO 15 show how a wire saw-specific correction profile may change in the course of the processing of a plurality of workpieces.

### DETAILED DESCRIPTION OF THE PREFERRED EMBODIMENTS

A semiconductor wafer cut from a workpiece has an upper and a lower side surface and an edge extending between the two. It is conventionally desired that, after cutting from the workpiece, the upper and the lower side surface are as planar as possible and have a maximally uniform distance from one another. The better the planarity of the side surfaces and the uniformity of the thickness of the semiconductor wafer at the start, the greater the success and the lower the outlay of refining the semiconductor wafer by subsequent steps such as lapping and/or grinding, etching, polishing and optionally coating to form a target product which meets the stringent requirements of the industry which processes the semiconductor wafer further to form electronic components. The upper side surface is also referred to as the front side of the semiconductor wafer, and is generally that surface on or into which the intention is to apply structures of electronic components in the course of further processing of the semiconductor wafer.

The present invention has the aim, when processing the workpiece by means of a wire saw, of ensuring that kerfs whose placement deviates as little as possible from a placement regarded as ideal are formed in the workpiece. If semiconductor wafers with a uniform thickness and maximally planar side surfaces are sought, an ideal kerf extends in a straight line and at a right angle to the longitudinal axis of the workpiece. In other words, the trajectory through the middle of such a kerf extends along a straight line which is oriented perpendicularly to the longitudinal axis of the workpiece. Such a trajectory will be referred to below as the target trajectory. Accordingly, there is a placement error of a kerf when the actual trajectory deviates from the target trajectory. This is the case when a position vector that points to the middle of the kerf no longer ends at the target trajectory.

A placement error of a kerf occurs, for example, when a wire moves perpendicularly to its running direction during its engagement into the workpiece, i.e. in the direction of the rotation axes of the wire guide rollers between which it is tensioned, or when the workpiece axially expands because of the development of heat during the feeding through the arrangement of wires. The placement error of a kerf is in the latter case commensurately greater when the kerf has a greater distance from the middle of the workpiece. The middle of the workpiece is the position between the two ends of the workpiece.

It is one aspect of the present invention to determine the placement error of the kerfs irrespective of the reason which has led to a relative movement between the workpiece and the wires. Examples of such reasons are movement of the wires, movement of the workpiece or thermal expansion of the workpiece. It is another aspect of the present invention to distinguish between a placement error of the kerfs which occurs systematically when using a particular wire saw and a placement error of the kerfs which occurs randomly and independently of the use of a particular wire saw.

Expediently, at least one closed control loop is set up, in which a control deviation, i.e. an ascertained placement error of the kerfs, is responded to with a modification of the manipulated variable, i.e. the induction of the compensating movement of the workpiece.

According to a first configuration of the invention, the determination of the placement error of the kerfs is carried out during the feeding of the workpiece through the arrangement of wires. Preferably, the position of each of the kerfs relative to a fixed reference point is measured and compared with a setpoint position. The setpoint position of a kerf is the position relative to the fixed reference point which would be required for an ideal kerf to be formed. The deviation of the measured position of the kerf from its setpoint position corresponds to the placement error of the kerf. Since the deviation is in principle different for each kerf, the deviations are averaged to give a placement error of the kerfs. In other words, each kerf is assigned the same placement error. The averaging may be carried out without weighting, or placement error of particular kerfs are especially weighted. From the placement error of the kerfs, a correction profile may be derived which specifies the magnitude and direction with which the workpiece must be moved during the feeding of the workpiece in order to eliminate the placement error of the kerfs. The correction profile has, considered over the penetration depth of the wires into the workpiece, a profile which is complementary to the profile of the ascertained placement error of the kerfs.

The measurement of the position of the kerfs relative to the fixed reference point is preferably carried out by means of irradiating the kerfs with optical radiation, IR radiation, X-radiation or γ radiation. Furthermore, mechanical sensing of the kerfs or inductive or capacitive measurement of the kerfs may also be envisioned. Such direct observation of the kerfs reveals any relative movement between the workpiece and the wires.

As a function of the ascertained placement error of the kerfs, during the feeding of the workpiece, a compensating movement of the workpiece, which is directed counter to the ascertained placement error, is induced along its longitudinal axis. The placement error of the kerfs is thus continuously reduced, and in the optimal case eliminated, during the feeding of the workpiece.

According to a second configuration of the invention, the determination of the placement error of the kerfs is carried out before the feeding of the workpiece through the arrangement of wires. By virtue of this procedure, a placement error of the kerfs which occurs systematically when using a particular wire saw is determined. In order to determine the placement error of the kerfs, the local geometry of semiconductor wafers which have been produced beforehand by means of a particular wire saw is measured. These semiconductor wafers come from one or more workpieces which have been processed by means of this wire saw. The local geometry of a semiconductor wafer approximately replicates the trajectory of the kerf next to the semiconductor wafer. Preferably, the local geometry of the median surface of a warp measurement according to SEMI MF 1390-0218 is obtained, specifically as follows: a height line (line scan, LS) is produced by selecting those measurement values of the median surface which lie on a line that extends through the center of the semiconductor wafer. The measurement values lie on a line that follows a diameter of the semiconductor wafer, preferably in the direction of the feeding of the workpiece when cutting the semiconductor wafer, or deviates from such a direction at least by no more than ±20°.

In order to identify a placement error of the kerfs which occurs systematically when using a particular wire saw, the local geometry of the semiconductor wafers which have been produced from one or more workpieces by means of this wire saw is averaged to give a single local geometry. The averaging may be carried out without weighting, or the local geometry of particular semiconductor wafers is specially weighted because of their relative placement in the workpiece. For example, during the averaging it is possible to take into account the local geometry only of those semiconductor wafers which have been obtained from the region of the middle or the region of one of the ends of one or more previously processed workpieces. On the basis of the averaged local geometry, it is then deduced how the trajectory of the kerfs will be if the particular wire saw is used and other influences that affect the trajectory are neglected. Such a trajectory will subsequently be referred to as the expected trajectory. The placement error of the kerfs, which is to be expected during the feeding of the workpiece, is obtained from comparison of the expected trajectory with the target trajectory. The comparison gives a wire saw-specific correction profile, which specifies the direction and magnitude of the compensating movement of the workpiece as a function of the penetration depth of the wires into the workpiece during the feeding of the workpiece through the arrangement of wires. The profile of the wire saw-specific correction profile is in principle complementary to the profile of the averaged local geometry.

The wire saw-specific correction profile is preferably also used in order to be able to promptly identify changes in the performance of the wire saw and respond thereto. Changes in the wire saw-specific correction profile which occur in the course of the processing of workpieces indicate wear of the wire and/or of the coating of the wire guide rollers or of another component of the wire saw which is subject to wear. A threshold may therefore be defined for the change in the wire saw-specific correction profile, with predictive maintenance measures being initiated when this is reached. Even before reaching such a threshold, changes in the wire saw-specific correction profile may be taken as a reason to carry out adaptation measures which counteract a wear-related degradation of the working outcome. Such adaptation measures may, for example, involve changing the composition and/or the temperature of a cutting medium suspension or changing the temperature of a coolant, as well as changing the wire speed or other process-specific parameters.

A third configuration involves combining the first and second configurations. A first part of the compensating movement of the workpiece is induced on the basis of a correction profile which is determined according to the first configuration of the invention in real time during the feeding of the workpiece as a function of the penetration depth of the wires. A further part of the compensating movement of the workpiece is induced on the basis of a wire saw-specific correction profile which has been determined according to the second embodiment of the invention before the feeding of the workpiece through the arrangement of wires. Randomly occurring and therefore unpredictable influences on the placement error of the kerfs, as well as those which occur systematically because of the use of a particular wire saw, are therefore taken into account separately from one another.

A wire saw-specific correction profile may, of course, also be obtained by recording the correction profile which is derived according to the first configuration of the method according to the invention.

The present invention may be used in conjunction with wires which comprise abrasive grain fixed on the wire, or in conjunction with wires which are free thereof and exert their effect in combination with a cutting medium suspension. In particular, diamond may be envisioned as the abrasive grain. The wires in question here are sections of a wire which is wound around the wire guide rollers of the wire saw. The number of wire guide rollers of the wire saw is not essential for the use of the invention. For example, the wire saw may comprise two, three, four or an even greater number of wire guide rollers.

The workpiece preferably consists of a semiconductor material such as silicon, which may be present in the polycrystalline or monocrystalline state. The contour of the workpiece is square, rectangular or circular. The method according to the invention is suitable, in particular, for the production of round semiconductor wafers of monocrystalline silicon with a diameter of at least 200 mm, in particular at least 300 mm.

The invention will be further explained below with reference to drawings.

### List Of References Used

1 sawing wire
2 groove
3 left wire guide roller
4 right wire guide roller
5 axis
6 axis
7 rotation
8 rotation direction
9 wire longitudinal movement
10 wire longitudinal movement
11 wire web
12 feed device
13 kerf
14 axis
15 workpiece
16 sawing strip
17 adhesive
18 arrow direction
19 nozzle row
20 nozzle row
21 nozzles
22 jet
23 jet
24 target trajectory

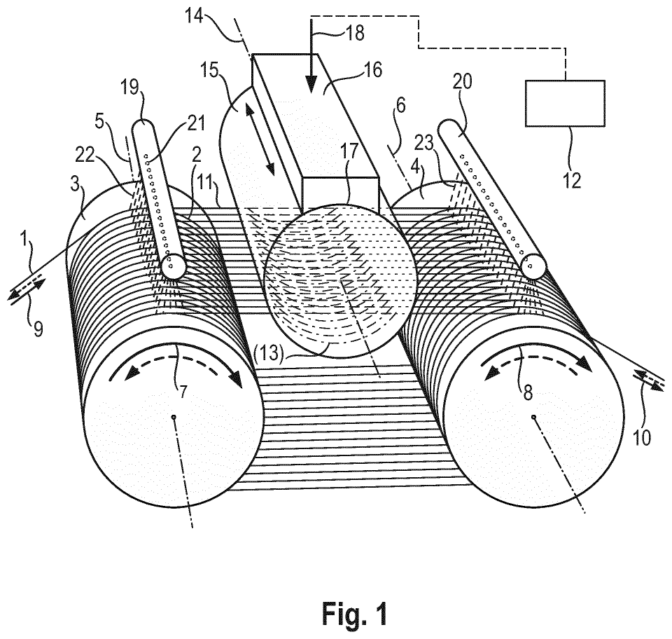

FIG. 1 shows features of a wire saw which is suitable for carrying out the method according to the invention. The wire saw comprises sawing wire 1 which is passed several times spirally around a left wire guide roller 3 and a right wire guide roller 4 and is guided by grooves 2 in such a way that the wire sections running on the upper side of the wire guide rollers, which are referred to as wires for the description of the present invention, run parallel and form a wire web 11. A workpiece 15 is fastened on a sawing strip 16, for example by means of an adhesive 17. The sawing strip 16 is fed with the workpiece 15 by a feed device 12 (represented indicatively) in arrow direction 18 perpendicularly against the wire web 11 and is brought into engagement with the wires of the web 11. Optionally, the wire saw comprises left nozzle rows 19 and right nozzle rows 20 with nozzles 21 for delivering a cutting medium suspension in the form of a left elongated jet 22 and a right elongated jet 23 onto the left wire guide roller 3 and the right wire guide roller 4.

The wire guide rollers are mounted rotatably about axes 5 and 6. Their axes and the axis 14 of the workpiece 15—in the example shown a cylindrical ingot—are oriented parallel to one another. In order to initiate the cutting process, one wire guide roller, for example the left wire guide roller 3, is driven in rotation 7 (master). The other wire guide roller (slave), in the example the right wire guide roller 4, corotates, pulled by wire 1, in the same sense in the rotation direction 8. When the wires engage into the workpiece 15, kerfs 13 are formed.

Conventionally, the direction of the wire longitudinal movement 9, 10 is reversed several times during a full cut through the workpiece 15 (dashed arrows), wherein in each individual one of these pairs of direction changes of the wire, referred to as a reciprocating movement, the wire is moved by a greater length in one direction and a shorter length in the opposite direction.

According to the invention, after the determination of the placement error of the kerfs, a compensating movement of the workpiece 15 is induced as a function of the ascertained placement error along the axis 14 of the workpiece 15, specifically on the basis of a correction profile and/or a wire saw-specific correction profile derived from the ascertained placement error of the kerfs. The double arrow 4 represents the compensating movement of the workpiece 15, which is brought about by the feed device 12.

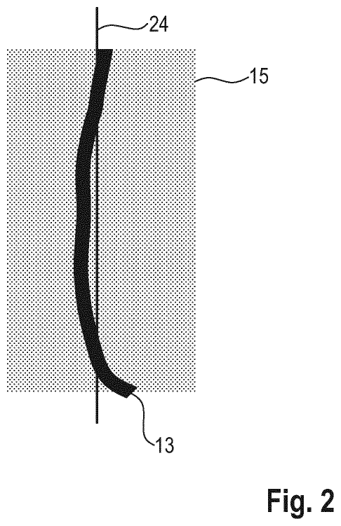

FIG. 2 shows in cross section an image which may be obtained by observing the kerfs during the engagement of the wires into the workpiece. It shows a part of the workpiece 15 and a kerf 13 which extends through the workpiece. The actual trajectory, which extends through the middle of the kerf 13, deviates more or less significantly from a target trajectory 24 during the formation of the kerf. The difference represents the ascertained placement error of the kerf 13. As mentioned, the invention proposes inducing a compensating movement of the workpiece as a function of the ascertained placement error of the kerfs along a longitudinal axis of the workpiece.

The comparison of the actual trajectory and the target trajectory according to the first configuration of the invention, or the comparison of the expected trajectory and the target trajectory according to the second configuration of the invention leads to a description of the profile of the placement error of the kerfs as a function of the penetration depth of the wires in the workpiece and to a correction profile (first configuration of the invention) or to a wire saw-specific correction profile (second configuration of the invention), which are respectively complementary with the profile of the placement error of the kerfs.

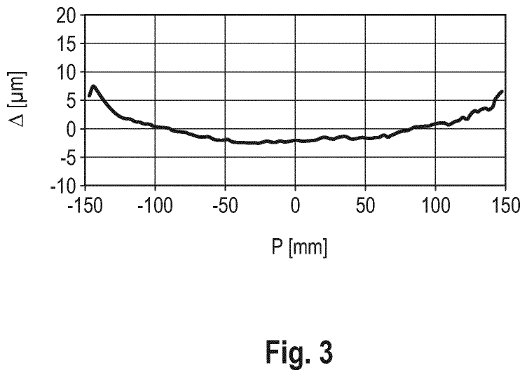

FIG. 3 shows a correction profile in which the deviation Δ of the actual trajectory from the target trajectory is plotted as a function of the penetration depth P of the wires. A compensating movement of the workpiece with a direction and a magnitude which corresponds to the deviation Δ is induced by the feed device. Only when there is no placement error of the kerfs (Δ=0), which in the example shown is not the case approximately until a penetration depth of −90 mm, is the inducing of the compensating movement of the workpiece stopped.

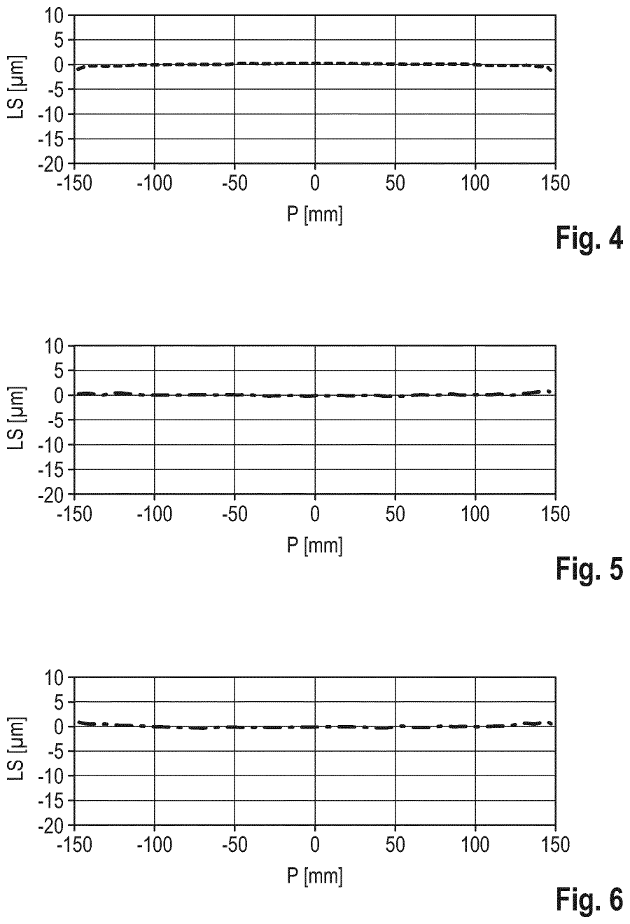

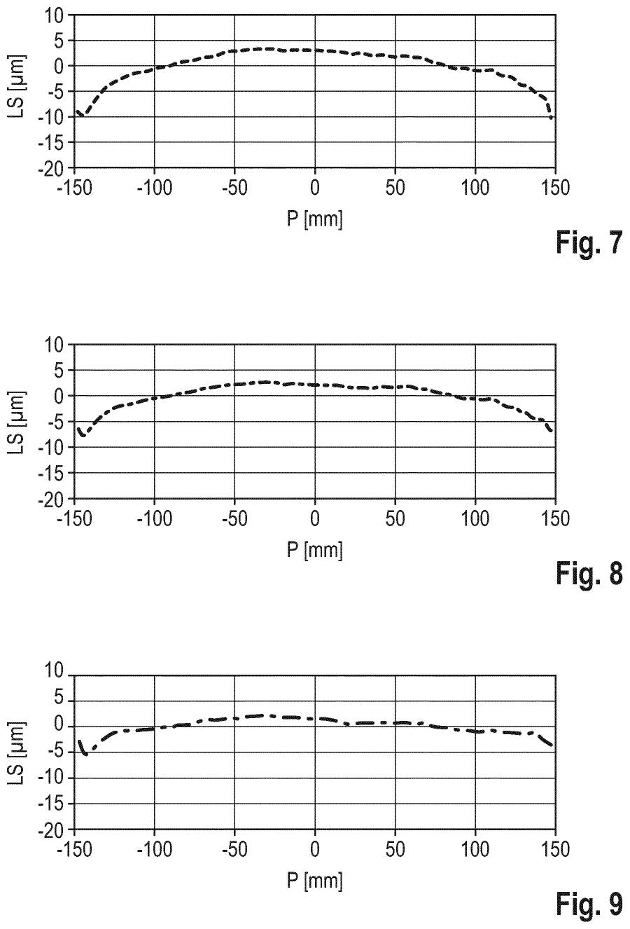

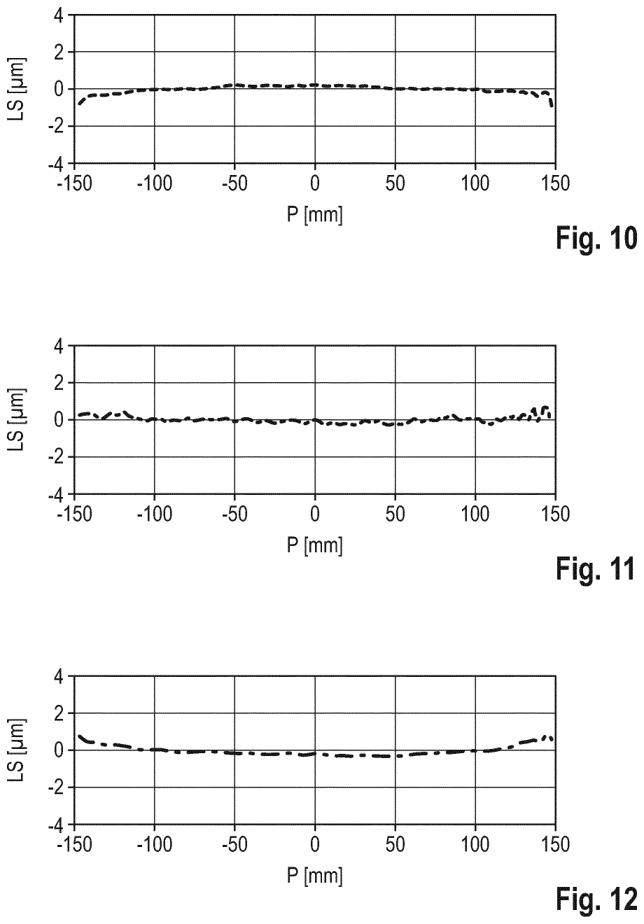

FIG. 4 to FIG. 9 show height lines LS respectively of three semiconductor wafers, which have been cut from a workpiece by wires of a wire web, a compensating movement of the workpiece, specified by the correction profile, having been induced during the cutting of the semiconductor wafers (FIG. 4 to FIG. 6), or the inducing of such a compensating movement having been omitted (FIG. 7 to FIG. 9). The height lines are respectively derived from the median surface of a warp measurement, with measurement values of the median surface having been selected which lie on a line that follows the diameter of the respective semiconductor wafer in the direction of the workpiece during the cutting of the semiconductor wafer. The position of the semiconductor wafers in the workplace was such that further semiconductor wafers were formed between each of the three semiconductor wafers 50 when cutting the semiconductor wafers. As the comparison of the height lines reveals, semiconductor wafers when using the invention are significantly more planar, and without a particular influence of their position in the workpiece. This is also confirmed by FIG. 10 to FIG. 12, which differ from FIG. 4 to FIG. 6 only in that the scaling of the ordinate is more highly resolved in them.

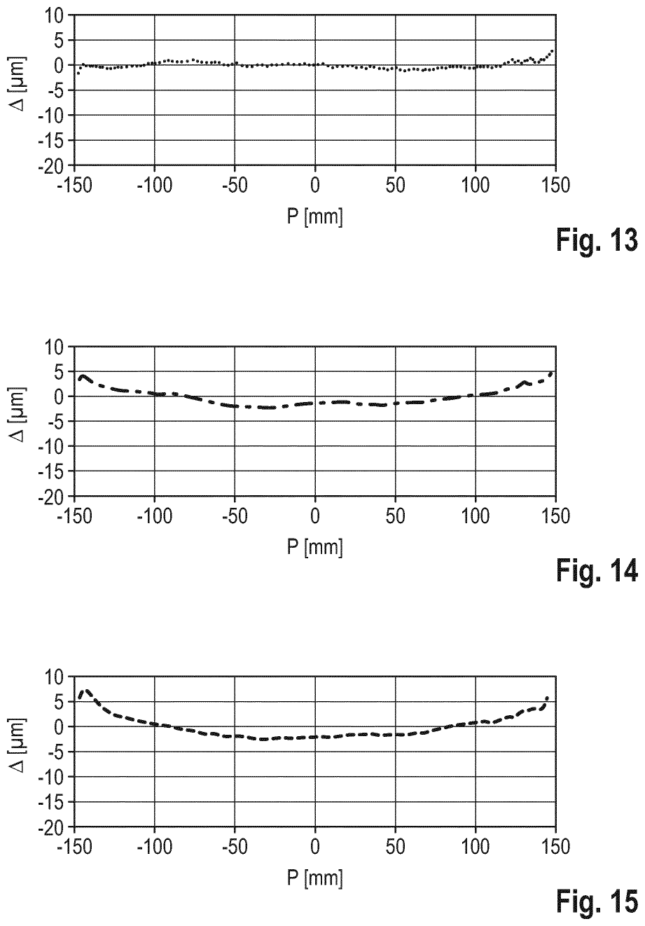

FIG. 13, 14 and 15 show how a wire saw-specific correction profile may vary constantly in the course of the processing of a plurality of workpieces. It is therefore advantageous to define a threshold for the deviation A, wherein predictive maintenance measures are initiated when it is exceeded. The threshold may, for example, be defined in such a way that only a wire saw-specific correction profile with a maximum deviation Δₘₐₓ, as is represented in FIG. 15, leads to predictive maintenance measures being initiated.

The preceding description of examples of embodiments is to be understood as exemplary. The disclosure thereby made on the one hand allows the person skilled in the art to understand the present invention and the advantages associated therewith, and on the other hand in the understanding of the person skilled in the art also comprises obvious changes and modifications to the described structures and methods. All such changes and modifications as well as equivalents are therefore intended to be covered by the scope of protection of the claims.

1.-5. (canceled)

6. A method for producing semiconductor wafers from a workpiece by processing the workpiece by means of a wire saw, comprising
feeding the workpiece through an arrangement of wires which are tensioned between wire guide rollers and move in a running direction;
producing kerfs when the wires engage into the workpiece;
determining at last one placement error of the kerfs; and
inducing a compensating movement of the workpiece as a function of the determined placement error(s) along a longitudinal axis of the workpiece during the feeding of the workpiece through the arrangement of wires.

7. The method of claim 6, comprising determining a placement error of the kerfs during the feeding of the workpiece through the arrangement of wires.

8. The method of claim 6, comprising determining a placement error of the kerfs by measuring the position of the kerfs by means of irradiating the kerfs with optical radiation, IR radiation, X-radiation or γ radiation, by mechanical sensing of the kerfs or by inductive or capacitive measurement of the kerfs, and comparing the measured position with a setpoint position of the kerfs.

9. The method of claim 7, comprising determining a placement error of the kerfs by measuring the position of the kerfs by means of irradiating the kerfs with optical radiation, IR radiation, X-radiation or γ radiation, by mechanical sensing of the kerfs or by inductive or capacitive measurement of the kerfs, and comparing the measured position with a setpoint position of the kerfs.

10. The method of claim 6, further comprising tracking changes in a wire saw-specific correction profile in the course of the processing of a plurality of workpieces, and initiating a predictive maintenance measure if the changes have exceeded an established threshold.

11. The method of claim 7, further comprising tracking changes in a wire saw-specific correction profile in the course of the processing of a plurality of workpieces, and initiating a predictive maintenance measure if the changes have exceeded an established threshold.

12. The method of claim 8, further comprising tracking changes in a wire saw-specific correction profile in the course of the processing of a plurality of workpieces, and initiating a predictive maintenance measure if the changes have exceeded an established threshold.

13. The method of claim 9, further comprising tracking changes in a wire saw-specific correction profile in the course of the processing of a plurality of workpieces, and initiating a predictive maintenance measure if the changes have exceeded an established threshold.

14. The method of claim 10, further comprising determining the placement error of the kerfs by measuring the local geometry of semiconductor wafers which have been produced beforehand by means of the wire saw, in order to compile the wire saw-specific correction profile.
